(19) United States
(12) Patent Application Publication
(10) Pub. No.: US 2009/0170033 A1
(43) Pub. Date: Jul. 2, 2009

(54) METHOD OF FORMING PATTERN OF SEMICONDUCTOR DEVICE

(75) Inventors: Woo Yung Jung, Seoul (KR); Guee Hwang Sim, Icheon-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 12/163,463

(22) Filed: Jun. 27, 2008

(30) Foreign Application Priority Data
Dec. 28, 2007 (KR) 2007-140328

(51) Int. Cl. G03F 7/20

(52) U.S. Cl. 430/313; 430/319

(57) ABSTRACT

The present invention relates to a method of forming patterns of a semiconductor device. In aspect of the present invention, a photoresist layer is formed on a semiconductor substrate. Exposure regions are formed in the photoresist layer to which light, which corresponds to an intermediate value of a maximum intensity and a minimum intensity of the light, is irradiated by performing an exposure process. Photoresist patterns are formed by removing the exposure regions.

### CROSS-REFERENCES TO RELATED APPLICATIONS

The present application claims priority to Korean patent application number 10-2007-0140328, filed on Dec. 28, 2007, which is incorporated by reference in its entirety.

### BACKGROUND OF THE INVENTION

The present invention relates to a semiconductor device and, more particularly, to a method of forming patterns in a semiconductor device by exposing a photoresist layer to different intensity bands of a light source at the time of an exposure process.

To form semiconductor devices, deposition and etching processes are performed repeatedly. For example, the deposition process can be performed to form layers, such as conductive layers and insulating layers, and the etch process can be performed to form patterns by removing deposited layers fully or partially.

In particular, as semiconductor devices become highly integrated, the width of features in a pattern is further narrowed, requiring further micro patterns. To this end, the patterning process has to be improved.

FIG. 1 is a view illustrating a conventional method of forming a pattern of a semiconductor device.

Photoresist patterns 12 are formed on a to-be-etched layer (or target layer) 10. The target layer 10 is etched by performing an etch process using the photoresist patterns 12 as an etch mask. Here, the photoresist patterns 12 can be formed by performing exposure and development processes after the photoresist layer is formed.

Specifically, a photoresist layer is formed on the target layer 10. Light is irradiated through slits 20 (e.g., photomask) which will transfer the pattern of the photomask 20 onto the photoresist layer. Here, light passing through aperture portions of the photomask 20 is irradiated to the photoresist patterns 12. At the time of a development process, regions which are exposed, depending on the type of the photoresist layer (e.g., positive or negative), are removed or remain, thereby forming the photoresist patterns 12. When using a positive photoresist (the most common type), the exposures regions 12a of the photoresist patterns 12 are regions to which light of the highest intensity is irradiated.

However, the wavelength λ of the light source determines the minimum feature size that can be produced using this conventional method. Due to the continuing need for higher levels of integration of semiconductor devices, the wavelength of available light sources inevitably leads to a limitation in forming smaller patterns.

### BRIEF SUMMARY OF THE INVENTION

The present invention is directed to form photoresist patterns having a narrower pitch than a limited pitch of an exposure process by using a photoresist layer exposed in a specific intensity of light at the time of the exposure process and to form micro patterns using the same.

According to an aspect of the present invention, there is provided a method of forming patterns of a semiconductor device. A photoresist layer is first formed on a semiconductor substrate. Exposure regions are formed in the photoresist layer to which light, which corresponds to an intermediate value of a maximum intensity and a minimum intensity of the light, is irradiated by performing an exposure process. Photoresist patterns are formed by removing the exposure regions.

The formation of the exposure regions can be performed after adjusting a height of slits or the semiconductor substrate so that the light corresponding to the intermediate value of the maximum intensity and the minimum intensity of the light is irradiated to target regions. Here, the slits can include patterns having a first pitch which is twice larger than a pitch to be formed finally.

According to another aspect of the present invention, there is provided a method of forming patterns of a semiconductor device. A target layer is formed on a semiconductor substrate in which a first region and a second region are partitioned. Hard mask layers are formed on the target layer. A first photoresist layer is formed over the hard mask layers. An exposure process is performed using first slits through which a part of the first region is opened, wherein first exposure regions having a width narrower than that of patterns of the first slits are formed. First photoresist patterns are formed by removing the first exposure regions. The hard mask layers are patterned on the first region along the first photoresist patterns.

After the hard mask layers on the first region are patterned, the first photoresist patterns are formed. A second photoresist layer is formed over the semiconductor substrate including the hard mask layers in which the first region is patterned. Second exposure regions having the same width as that of patterns of second slits are formed by performing an exposure process using the second slits through which a part of the second region is exposed. Second photoresist patterns are formed by removing the second exposure regions. The hard mask layers of the second region are patterned along the second photoresist patterns. The second photoresist patterns are removed. The target layer is patterned along hard mask patterns in which the first and second regions are patterned.

Portions of the first photoresist layer, which are irradiated by light of an intermediate intensity band at the time of an exposure process, can react to the light and thus exposed.

Portions of the first photoresist layer, which are irradiated by light of maximum and minimum intensity bands at the time of an exposure process, can be not exposed.

### BRIEF DESCRIPTION OF THE DRAWINGS

FIG. 1 is a view illustrating a conventional method of forming patterns of a semiconductor device;

FIGS. 2A and 2B are sectional views illustrating a method of forming patterns of a semiconductor device in accordance with an embodiment of the present invention; and

FIGS. 3A to 3G are sectional views illustrating a method of forming patterns of a semiconductor device in accordance with another embodiment of the present invention.

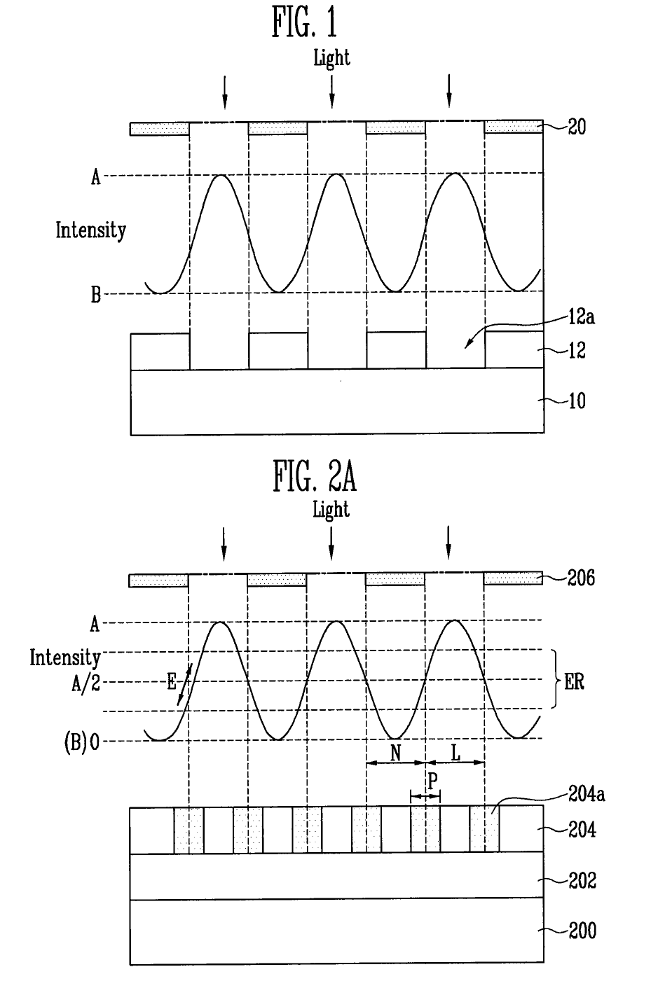

### DESCRIPTION OF SPECIFIC EMBODIMENTS

Specific embodiments according to the present invention will be described with reference to the accompanying drawings. However, the present invention is not limited to the disclosed embodiments, but may be implemented in various manners. The embodiments are provided to complete the disclosure of the present invention and to allow those having ordinary skill in the art to understand the scope of the present invention. The present invention is defined by the category of the claims.

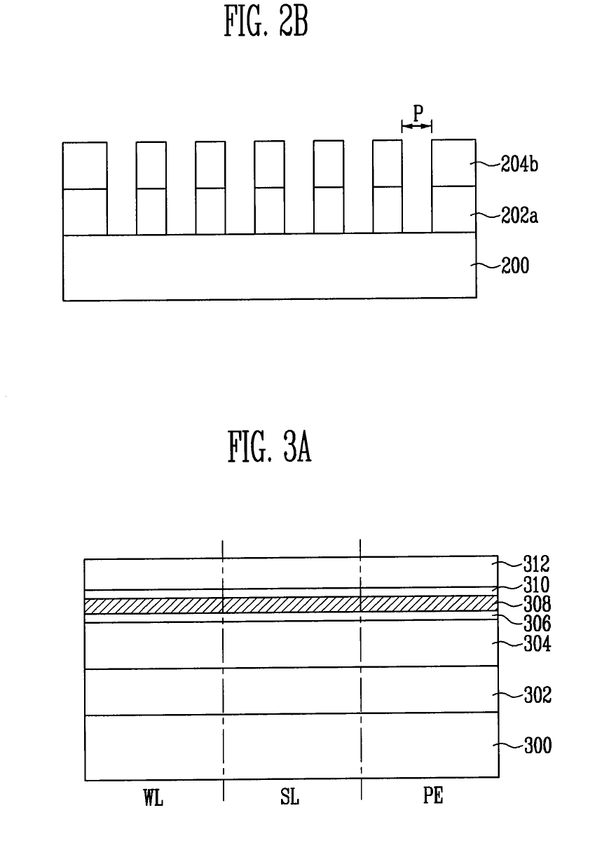

FIGS. 2A and 2B are sectional views illustrating a method of forming patterns of a semiconductor device in accordance with an embodiment of the present invention. A target layer 202 is formed on a semiconductor substrate 200. The target layer 202 can be formed of an insulating layer, a metal layer, a gate electrode layer, a hard mask layer, or other types. Photoresist layers 204 for patterning the target layer 202 are formed on the target layer 202. The exposure regions of the photoresist layers 204 have its bonding force weakened by the intensity of light irradiated at the time of an exposure process. The exposure regions having weakened bonding force as described above can be removed easily in a subsequent development process. The photoresist layers 204 can be patterned in this manner. In particular, the present embodiment employs the photoresist layers 204, which reacts to an intensity corresponding to an intermediate intensity of light irradiated at the time of an exposure process

More specifically, if an exposure process is performed using a photomask having patterns formed thereon, a light intensity wave is generated. For example, a wave has a sine shape. A length of the wave is changed according to a pattern of slits used, but maximum and minimum intensity values of the wave are not changed since they are a unique value of the light. Here, it is assumed that a maximum intensity value of the light is ‘A’ and a minimum intensity value of the light is ‘B’. Assuming that the minimum intensity is ‘0’ for convenience of description, the positions of slits 206 are adjusted or the height of the semiconductor substrate 200 is adjusted such that light of an intensity corresponding to half (A/2) of the maximum intensity A, is irradiated to target regions of the photoresist layers 204. Hence, exposure regions 204a are formed in the photoresist layers 204 to which light corresponding to the A/2 intensity band E of the light has been irradiated. In other words, an exposure reaction does not occur in regions L to which light of the maximum intensity A is irradiated and regions N to which light of the minimum intensity 0 is irradiated, of the photoresist layers 204, but occurs in intermediated regions P.

That is, the exposure regions 204a are formed between regions to which the maximum intensity of light is irradiated and regions to which the minimum intensity of light is irradiated. Thus, the exposure regions 204a are double the exposure regions to which a maximum intensity or a minimum intensity of light is irradiated. That is, each wave defines two exposure regions instead of one as in the conventional method.

Referring to FIG. 2B, the exposure regions (refer to 204a of FIG. 2A) are removed by performing a development process. Thus, dense photoresist patterns 204b, having a half pitch when compared with a case where positive or negative photoresist layers are used, can be formed. The target layer (refer to 202 of FIG. 2A) can be patterned using the photoresist pattern 204b in order to form patterns 202a.

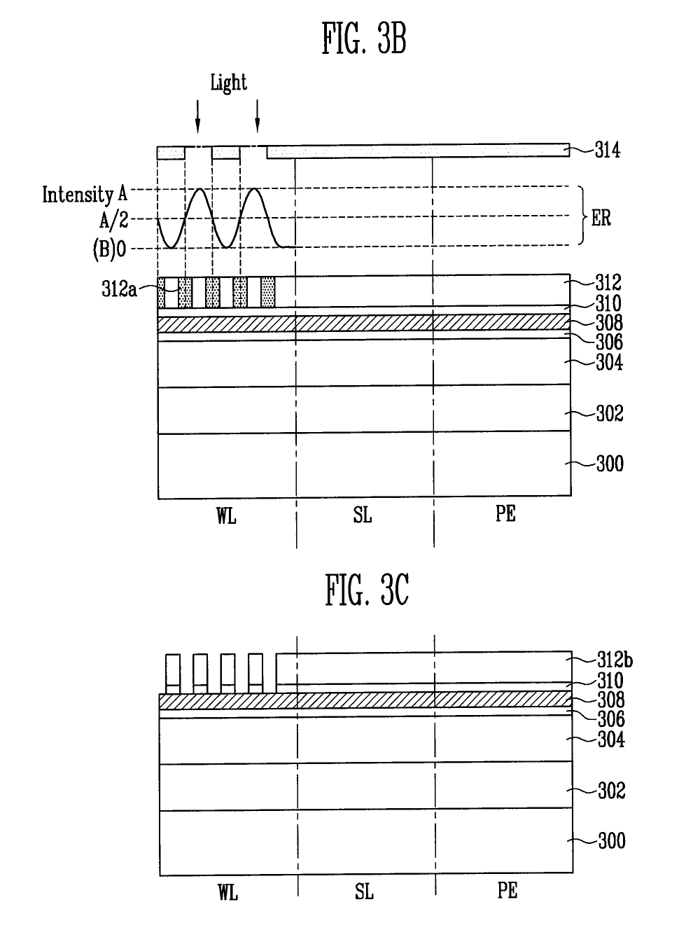

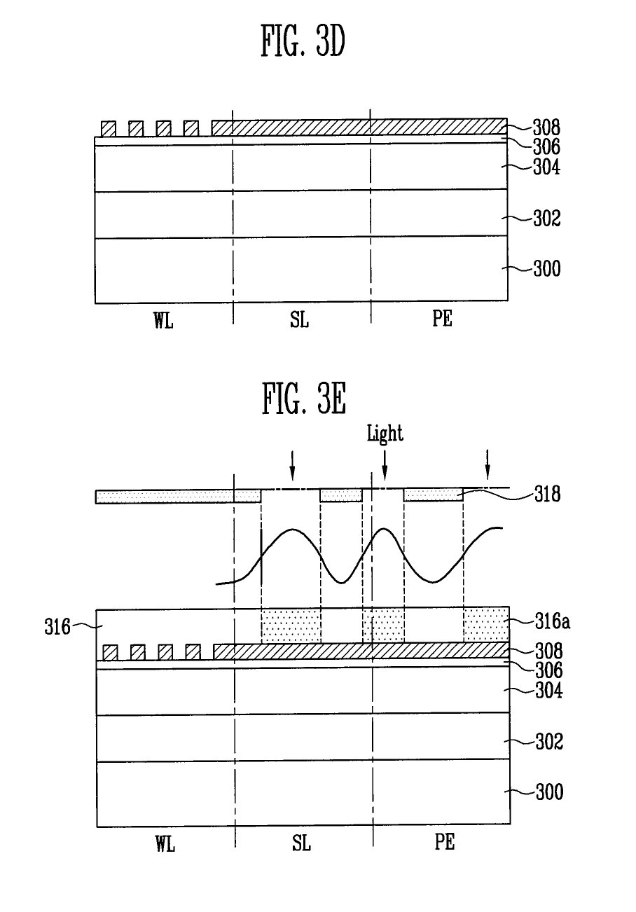

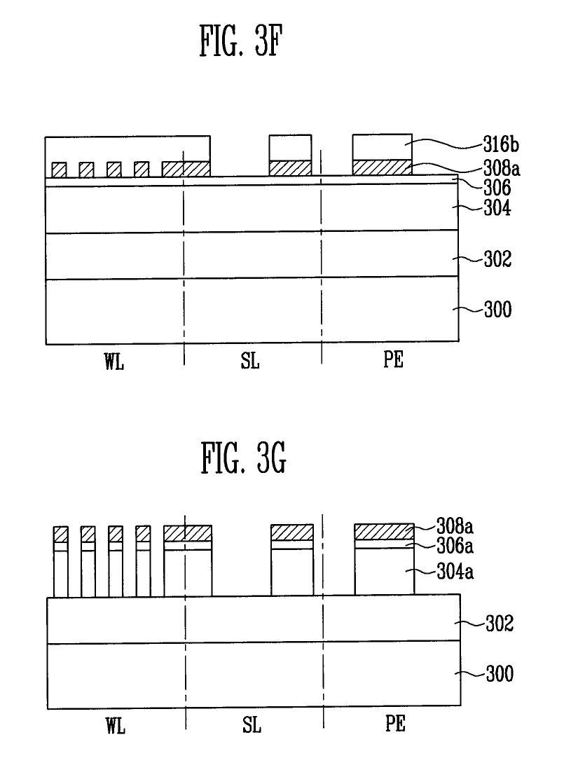

FIGS. 3A to 3G are sectional views illustrating a method of forming patterns of a semiconductor device in accordance with another embodiment of the present invention.

Referring to FIG. 3A, there is provided a semiconductor substrate 300 in which a word line region WL, a select line region SL and a peri region PE are defined. A target layer 302 is formed on the semiconductor substrate 300. The target layer 302 may be a metal layer, an insulating layer or a gate layer depending on its intended purpose. A first hard mask layer 304, a second hard mask layer 306, a third hard mask layer 308 and a BARC (Bottom Anti-Reflective Coating) layer 310 are sequentially formed over the target layer 302. For example, the first hard mask layer 304 may be a SOC (Spin On Carbon) layer or an amorphous carbon layer. The second hard mask layer 306 and the third hard mask layer 308 can be formed using materials with a different etch selectivity. The second hard mask layer 306 may be a SiON layer or a polysilicon layer, and the third hard mask layer 308 may be a polysilicon layer or a SiON layer. A first photoresist layer 312, which has an exposure reaction in an intermediate energy band (A/2 of FIG. 3B) of light (light irradiated at the time of an exposure process), is formed on the BARC layer 310.

Referring to FIG. 3B, an exposure process is performed on the word line region WL by using first slits in which aperture portions are formed. Specifically, the pitch of the first slits is twice that of the patterns to be formed in the word line region WL. Exposure regions 312a are formed in the word line region WL of the first photoresist layer 312 by performing an exposure process along the first slits. Here, the height of the slit 314 or the height of the semiconductor substrate 300 can be adjusted so that an intensity (A/2) of light, corresponding to about half of the light intensity, is irradiated to target regions of the first photoresist layer 312. Hence, regions in the photoresist layer 312 which receives light of half intensity (A/2), reacts, thus forming the exposure regions 312a.

Referring to FIG. 3C, the exposure regions 312a of the first photoresist layers (refer to 312 of FIG. 3B) are removed by performing a development process. Thus, first photoresist patterns 312b having a second pitch, which is half the first pitch, can be formed in the word line region WL. The BARC layer 310 of the word line region is patterned by performing an etch process using the first photoresist patterns 312b.

Referring to FIG. 3D, the third hard mask layer 308 is patterned by performing an etch process using the first photoresist patterns (refer to 312b of FIG. 3C) and the patterned BARC layer (refer to 310 of FIG. 3C). The remaining first photoresist patterns (refer to 312b of FIG. 3C) and the remaining BARC layer 310 are then removed.

Referring to FIG. 3E, a second photoresist layer 316 is formed on the third hard mask layer 308, gap filling the patterned word line region WL. The second photoresist layer 316 employs a photoresist layer (e.g., positive photoresist) that reacts to light corresponding to a maximum intensity band (light used at the time of an exposure process).

Second slits 318 having aperture portions formed over the select line region SL and the peri region PE are loaded. Exposure regions 316a are formed in the second photoresist layer 316 of the select line region SL and the peri region PE by performing an exposure process along the second slits 318. Here, the height of the slit 318 or the semiconductor substrate 300 can be adjusted and the exposure process can then be performed so that light corresponding to a maximum intensity of light is irradiated onto the second photoresist layers 316.

Referring to FIG. 3F, the exposure regions (refer to 316a of FIG. 3E) of the second photoresist layer (refer to 316 of FIG. 3E) are removed by performing a development process. Thus, second photoresist patterns 316b in which the select line region SL and the peri region PE are patterned can be formed. Third hard mask patterns 308a are then formed by patterning the third hard mask layer (refer to 308 of FIG. 3E) using the second photoresist patterns 316b. Accordingly, the third hard mask patterns 308a can be formed in the word line region WL, the select line region SL and the peri region PE.

Referring to FIG. 3G, the second photoresist patterns (refer to 316b of FIG. 3F) are removed. Second hard mask patterns 306a and first hard mask patterns 304a are then formed by patterning the second and first hard mask layers (refer to 306 and 304 of FIG. 3F) using the third hard mask patterns 308a.

Although not shown in the drawings, the target layer 302 is patterned using the third, second and first hard mask patterns 308a, 306a and 304a.

As described above, according to the present invention, patterns having a narrower pitch than a limited pitch of an exposure process can be formed by using a photoresist layer exposed in a specific intensity band of light at the time of an exposure process. Accordingly, micro patterns can be formed without replacing an exposure apparatus.

The embodiments disclosed herein have been proposed to allow a person skilled in the art to easily implement the present invention, and the person skilled in the part may implement the present invention by a combination of these embodiments. Therefore, the scope of the present invention is not limited by or to the embodiments as described above, and should be construed to be defined by the appended claims and their equivalents.

What is claimed is:

1. A method for forming patterns on a semiconductor device, the method comprising:
providing a photomask over a substrate, the photomask including a plurality of slits having a first pitch;
forming a photoresist layer over a target layer that is provided over the substrate;
emitting light through the slits of the photomask, the light emitted through the slits of the photomask defining a wave having a maximum intensity, a first intermediate intensity, a second intermediate intensity, and a minimum intensity at a first location, a second location, a third location, and a fourth location of the photoresist layer, respectively; and
removing portions of the photoresist layer corresponding to the second and third locations to form photoresist patterns.

2. The method of claim 1, wherein, the photoresist layer includes material that reacts to an intermediate intensity of the light that passed through the slits.

3. The method of claim 1, wherein the slits of the photomask define a first pitch and the photoresist patterns define a second pitch, wherein the second pitch is twice as smaller than the first pitch.

4. The method of claim 1, wherein the first intermediate intensity is of substantially the same intensity as that of the second intermediate intensity.

5. The method of claim 1, further comprising;
adjusting a distance between the photomask and the photoresist layer.

6. The method of claim 5, wherein the adjusting step is performed before performing the emitting step.

7. The method of claim 6, wherein the adjusting step is performed by adjusting a height of the photomask or the substrate so that the light corresponding to the first intermediate intensity and the second intermediate intensity is irradiated onto the photoresist layer.

8. The method of claim 1, wherein photoresist layer includes.

9. The method of claim 1, further comprising:
etching the target layer using the photoresist patterns.

10. A method for forming patterns on a semiconductor device, the method comprising:
forming a target layer over a substrate in which a first region and a second region are defined;
forming first and second hard mask layers over the target layer;
forming a first photoresist layer over the hard mask layers, the first photoresist layer including material that reacts to an intermediate intensity of light;
providing a first photomask having a first portion and a second portion corresponding, respectively, to the first region and the second region of the substrate, the first portion of the first photomask having a plurality of slits that define a first pitch, the second portion of the first photomask having no slit;
emitting light through the slits of the first portion of the first photomask to expose the first region of the substrate to the light;
providing the first photoresist layer with first photoresist patterns at the first region, the first photoresist patterns having a second pitch that is smaller than the first pitch; and
patterning the first hard mask layer on the first region using the first photoresist patterns.

11. The method of claim 10, further comprising:
removing the first photoresist patterns after patterning the first hard mask layer on the first region;
forming a second photoresist layer over the first and second hard mask layers;
emitting light through a second photomask having a first portion and a second portion corresponding, respectively, to the first region and the second region of the substrate, the first portion of the second photomask having no slit, the second portion of the second photomask having a plurality of slits that define a third pitch;
providing the second photoresist layer with second photoresist patterns at the second region, the second photoresist patterns defining a fourth pitch, the third pitch and the fourth pitch being substantially the same;
patterning at least the first hard mask layer at the second region using the second photoresist patterns; and
patterning the target layer using at least the first hard mask layer that has been patterned at the first and second regions.

12. The method of claim 11, wherein the second hard mask layer is patterned at the second region using the second photoresist patterns.

13. The method of claim 10, wherein portions of the first photoresist layer that are irradiated with the light of an intermediate intensity are removed to form the first photoresist patterns.

14. The method of claim 10, wherein portions of the first photoresist layer that are irradiated with the light of maximum or minimum intensity are not removed to form the first photoresist patterns.
